(19) United States
(12) Patent Application Publication
(10) Pub. No.: US 2002/0066937 A1
(43) Pub. Date: Jun. 6, 2002

(54) Structure of a semiconductor module and method of manufacturing the same

(76) Inventor: Takashi Hosaka, Chiba-shi (JP)

Correspondence Address: ADAMS & WILKS, 31st Floor, 50 Broadway, New York, NY, 10004, US

(21) Appl. No.: 09/966,716

(22) Filed: Sep. 27, 2001

(30) Foreign Application Priority Data
Oct. 30, 2000 (JP) 2000-331081

(51) Int. Cl. H01L 31/0203

(52) U.S. Cl. 257/433

(57) ABSTRACT

There is provided a semiconductor module that can be easily manufactured and has a photosensitive element. A method of manufacturing the module comprises the steps of: adhering a sheet made of a light shielding material onto a module having a photosensitive element; breaking the sheet by a protrusion of a light receiving portion in a module surface through which light reaches the photosensitive element; and covering at least a portion of a region except for the light receiving portion.

### BACKGROUND OF THE INVENTION

1. Field of the Invention

The present invention relates to a module including a photosensitive element and a method of manufacturing the same.

2. Description of the Related Art

A conventional structure of a module including a photosensitive element is shown in FIG. 2. That is, in the module shown in FIG. 2, a photosensitive element, that is, a light receiving element 22, a control IC 23 for processing a signal from the light receiving element 22, and an attachment chip part 24 are mounted on a substrate 21. As the light receiving element 22, there is, for example, a photodiode, a solar battery, or the like. As the chip part 24, there is a resistor, a capacitor, or an inductor. The above element and part are covered with a package rein 25. As this package rein 25, a resin which can maximize the amount of light entering the light receiving element 22, that is, a resin that is transparent with respect to the entering light is selected. The above element and part are protected by the package resin 25 from a mechanical shock and an environment in which the module is set.

A light receiving portion 26 of the module is formed into a lens shape in order to maximize the convergence of light into the light receiving element 22.

Generally, when elements except for the light receiving element 22 are irradiated with light, it is likely to cause a noise. Thus, as shown in FIG. 2, these elements are covered with the metal case 27. This metal case 27 covers the surface of the module except for the light receiving portion 26.

The metal case 27 must be formed corresponding to the module. When this metal case 27 is manufactured, a large number of processes such as bending, welding, and punching of a metal plate, must be performed. Thus, a manufacturing cost becomes considerably higher. Also, the metal case and the module must be formed in separate processes, and thus spending on manufacturing facility becomes substantial. Further, since a process for attaching the metal case to the module must be added thereafter, the number of processes is greatly increased. This causes substantial increase in a cost.

### SUMMARY OF THE INVENTION

In order to solve the above problems, according to the present invention, a light shielding sheet is adhered onto a module in a region except for a light receiving portion. Thus, since the light shielding sheet is provided in a portion where a problem occurs if it is irradiated with light, light is not incident upon this portion. In addition, since the light shielding sheet is produced in a size corresponding to that of the module, this sheet can be adhered to the module by an automatic apparatus.

### BRIEF DESCRIPTION OF THE DRAWINGS

In the accompanying drawings:

FIG. 1 shows a structure of a semiconductor module according to the present invention;

FIG. 2 shows a structure of a conventional semiconductor module;

FIGS. 3A and 3B show a manufacturing method of the semiconductor module according to the present invention; and

FIGS. 4A and 4B show the manufacturing method of the semiconductor module according to the present invention.

### DETAILED DESCRIPTION OF THE PREFERRED EMBODIMENTS

The present invention is to provide a simple method of preventing light irradiation to a portion where a problem occurs if it is irradiated with light, in a module including a photosensitive element.

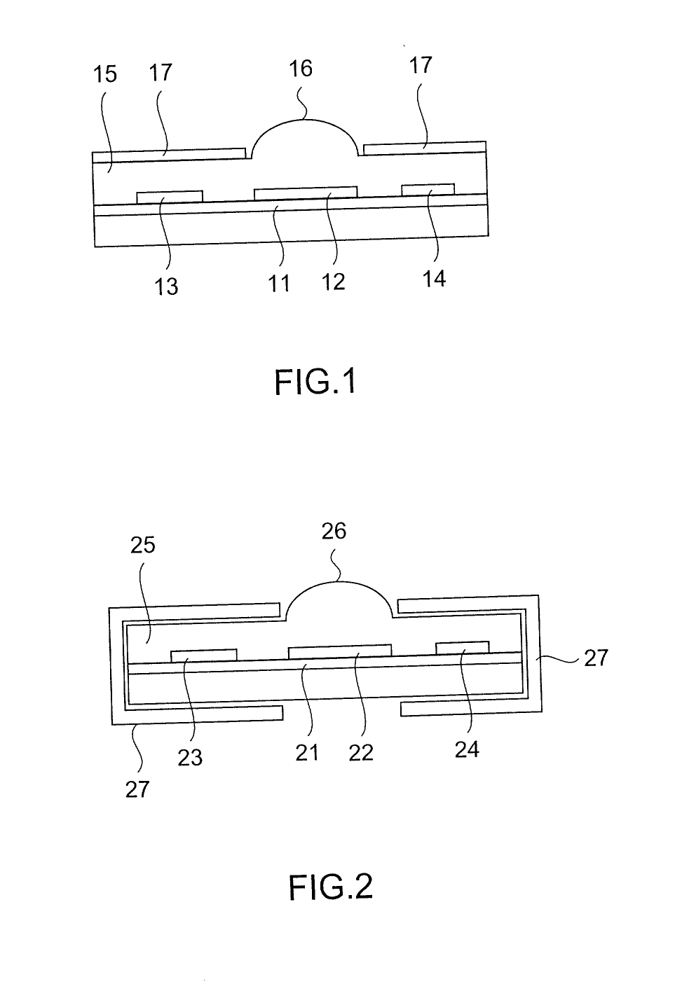

FIG. 1 shows a structure of a module of the present invention. That is, a light shielding sheet is adhered to a region except for a light receiving portion. That is, in FIG. 1, a light receiving element 12, a control IC 13 for processing a signal from the light receiving element 12, and another chip part 14 are mounted on a substrate 11. The light receiving element 12, the control IC 13, and the chip part 14 are covered with a package resin 15 and thus mechanically or environmentally protected. As the package resin 15, a resin is selected so that light is efficiently entered into the light receiving element 12. In many cases, a light receiving portion 16 is formed into a lens shape such that light is entered into the light receiving element 12 with higher efficiency. Needless to say, if not necessary, the light receiving portion 16 may not be formed into a lens shape. When an element and a part except for the light receiving element 12 are irradiated with light, since there is the case where a noise signal is generated, it is required that they are not irradiated with light. Therefore, as shown in FIG. 1, a light shielding sheet 17 is adhered onto a region except for the light receiving portion 16 of the module. Since an adhesive is provided to the sheet 17, the sheet 17 can be tightly adhered onto the surface of the module.

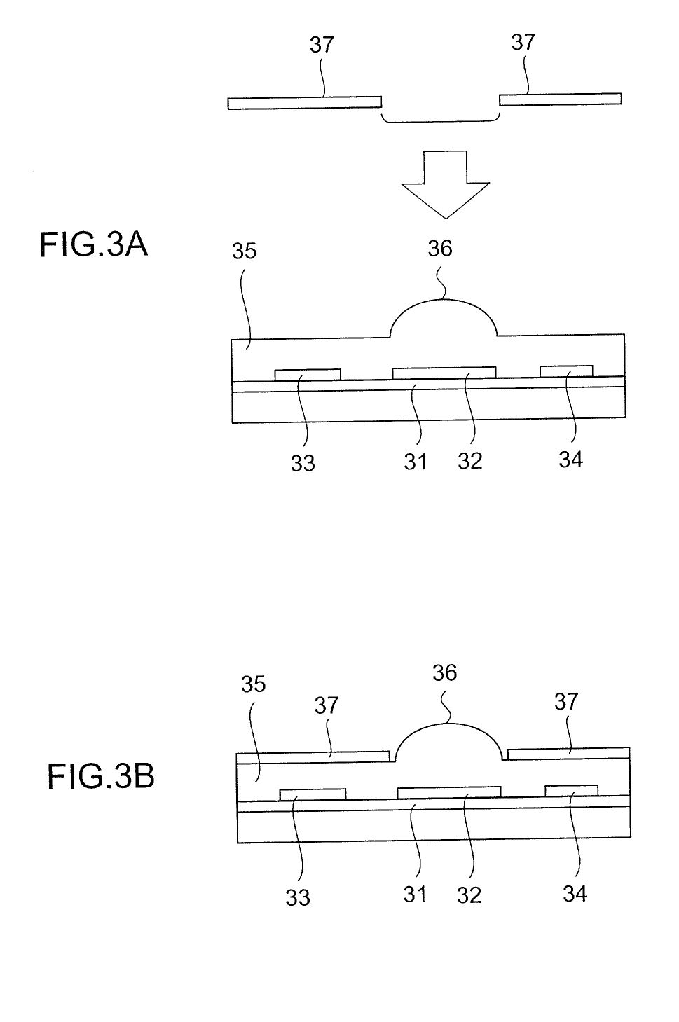

FIGS. 3A and 3B show one example of a sheet adhering method. That is, as shown in FIG. 3A, a sheet 37 in which a hole 38 is formed in a region corresponding to a light receiving portion 36 is produced. This light shielding sheet 37 is aligned with the semiconductor module. Then, as shown in FIG. 3B, the light shielding sheet 37 is adhered to the module. That is, in FIG. 3, a light receiving element 32, a control IC 33 for processing a signal from the light receiving element 32, and another chip part 34 are mounted on a substrate 31. The light receiving element 32, the control IC 33, and the chip part 34 are covered with a package resin 35 and thus mechanically or environmentally protected. As the package resin 35, a resin is selected so that light is efficiently entered into the light receiving element 32. In many cases, a light receiving portion 36 is formed into a lens shape such that light is entered into the light receiving element 32 with higher efficiency. Needless to say, if not necessary, the light receiving portion 36 may not be formed into a lens shape.

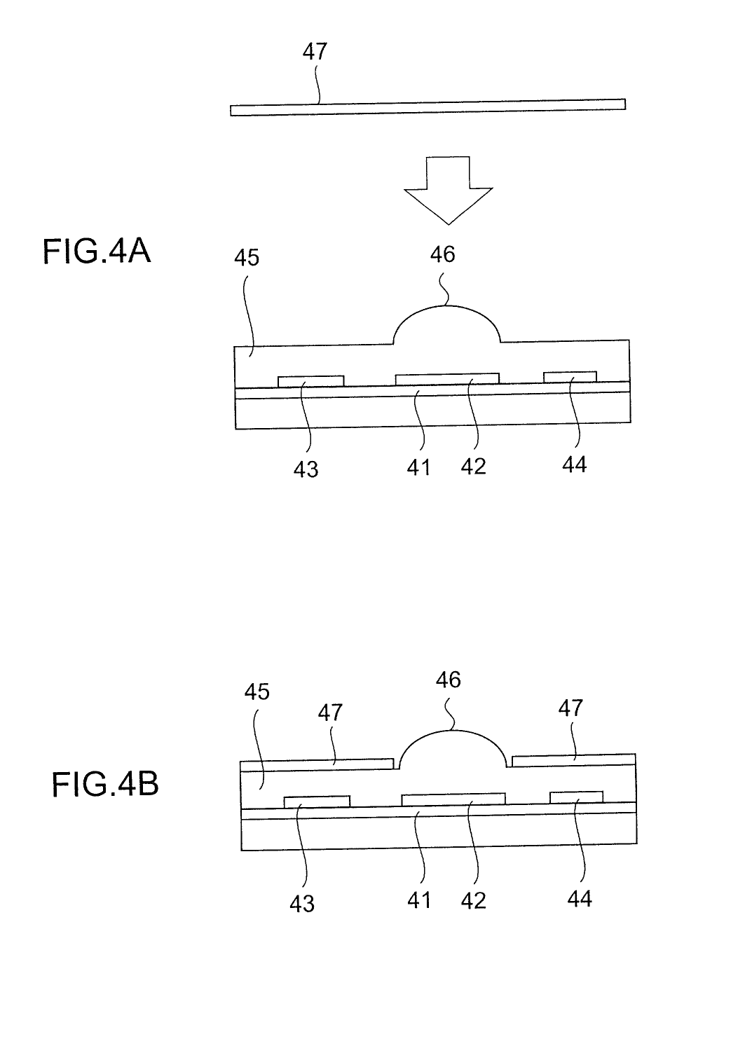

As another example, as shown in FIG. 4, when a light shielding sheet 47 is extended and then is adhered to the module, the sheet 47 is broken by using the protrusion of a light receiving portion 46 and adhered to the region except for the light receiving portion 46. Or, after the sheet 47 is adhered to the surface of the module without breaking the sheet 47, a region of the sheet 47, which is adhered to the light receiving portion 46, may be penetrated. . That is, in FIG. 4, a light receiving element 42, a control IC 43 for processing a signal from the light receiving element 42, and another chip part 44 are mounted on a substrate 41. The light receiving element 42, the control IC 43, and the chip part 44 are covered with a package resin 45 and thus mechanically or environmentally protected. As the package resin 45, a resin is selected so that light is efficiently entered into the light receiving element 42. In many cases, a light receiving portion 46 is formed into a lens shape such that light is entered into the light receiving element 42 with higher efficiency. Needless to say, if not necessary, the light receiving portion 46 may not be formed into a lens shape.

As described above, according to the present invention, the light shielding sheet is adhered to the module. Thus, the module is manufactured using a very simple process. Also, the manufacturing cost and the material cost can be greatly reduced compared to the conventional case where a metal case is used.

What is claimed is:

1. A module comprising:
a substrate, a photosensitive element and a control integrated circuit connected to the element on the substrate, a package resin on the surface of the element and the integrated circuit, and a film containing a materials for shielding light over the surface of the integrated circuit.

2. A method of manufacturing a module comprising the steps of:
forming a photosensitive element and a control integrated circuit connected to the element on a substrate; and
forming a sheet which is made of a light shielding material and in which a hole is formed in advance in a region corresponding to a light receiving portion in a module surface through which light reaches the photosensitive element, adhereing the sheet onto the module to cover at least a portion of a region except for the light receiving portion.

3. A method of manufacturing a module, comprising the steps of:
adhering a sheet made of a light shielding material onto a module having a photosensitive element;
breaking the sheet by a protrusion of a light receiving portion in a module surface through which light reaches the photosensitive element; and
covering at least a portion of a region except for the light receiving portion.
